(19) United States
(12) Patent Application Publication
(10) Pub. No.: US 2024/0030021 A1
(43) Pub. Date: Jan. 25, 2024

(54) LASER PROCESSING APPARATUS AND LASER PROCESSING METHOD

(71) Applicant: Tokyo Electron Limited, Tokyo (JP)

(72) Inventors: Yohei YAMASHITA, Kikuchi-gun, Kumamoto (JP); Yasutaka MIZOMOTO, Kikuchi-gun, Kumamoto (JP)

(21) Appl. No.: 18/044,386

(22) PCT Filed: Aug. 27, 2021
(86) PCT No.: PCT/JP2021/031569

§ 371 Date: Mar. 8, 2023

(30) Foreign Application Priority Data
Sep. 9, 2020 (JP) 2020-151606

(51) Int. Cl. H01L 21/02; H01L 21/67; H01L 21/66; B23K 26/361; B23K 26/03; B24B 7/22

(52) U.S. Cl. CPC H01L 21/02035; H01L 21/67115; H01L 21/67207; H01L 21/67288; H01L 21/02013; H01L 21/02019; H01L 22/20; B23K 26/361; B23K 26/032; B24B 7/22; B23K 2103/56

(57) ABSTRACT

A laser processing apparatus includes a holder configured to hold a substrate obtained by slicing a single crystal ingot; a light source configured to oscillate a laser beam to be radiated to a first main surface of the substrate; a moving unit configured to move a position of a radiation point of the laser beam on the first main surface of the substrate in a state that the substrate is held by the holder; and a controller configured to control the light source and the moving unit. The controller controls the light source and the moving unit to radiate the laser beam to the first main surface of the substrate to remove a surface layer of the first main surface of the substrate, so that fragment adhering to the first main surface during the slicing of the single crystal ingot is removed.

### TECHNICAL FIELD

The various aspects and embodiments described herein pertain generally to a laser processing apparatus and a laser processing method.

### BACKGROUND

Patent Document 1 describes a processing method of a semiconductor wafer. In this processing method, a semiconductor wafer obtained by slicing a single crystal ingot is subjected to a chamfering process, a wrapping process, an etching process, and a mirror polishing process.

### PRIOR ART DOCUMENT

Patent Document 1: Japanese Patent Laid-open Publication No. 2002-203823

### DISCLOSURE OF THE INVENTION

### Problems to be Solved by the Invention

Exemplary embodiments provide a technique of removing fragment adhering to a substrate during the slicing of a single crystal ingot and suppressing the occurrence of a defect in the substrate due to the fragment.

### Means for Solving the Problems

In an exemplary embodiment, a laser processing apparatus includes a holder, a light source, a moving unit and a controller. The holder is configured to hold a substrate obtained by slicing a single crystal ingot. The light source is configured to oscillate a laser beam to be radiated to a first main surface of the substrate. The moving unit is configured to move a position of a radiation point of the laser beam on the first main surface of the substrate in a state that the substrate is held by the holder. The controller controls the light source and the moving unit to remove a surface layer from an entire of the first main surface of the substrate.

### Effect of the Invention

According to the exemplary embodiments, it is possible to remove the fragment adhering to the substrate during the slicing of the single crystal ingot and suppress the occurrence of the defect in the substrate due to the fragment.

### BRIEF DESCRIPTION OF THE DRAWINGS

FIG. 1 is a plan view showing a laser processing apparatus according to an exemplary embodiment.

FIG. 2 is a front view of the laser processing apparatus of FIG. 1.

FIG. 3A is a side view illustrating an example of a substrate before being subjected to a laser processing, and FIG. 3B is a side view illustrating an example of the substrate after being subjected to the laser processing.

FIG. 4 is a flowchart illustrating a laser processing method according to the exemplary embodiment.

FIG. 5 is a diagram illustrating an example of a waveform measuring module.

FIG. 6 is a diagram illustrating an example of a laser processing module.

FIG. 7A is a diagram illustrating a first example of an intensity distribution of a laser beam, and FIG. 7B is a diagram illustrating a second example of the intensity distribution of the laser beam.

FIG. 8A is a plan view showing a first example of a radiation point arrangement method, FIG. 8B is a plan view showing a second example of the radiation point arrangement method, and FIG. 8C is a plan view showing a third example of the radiation point arrangement method.

### DETAILED DESCRIPTION

Hereinafter, exemplary embodiments of the present disclosure will be described with reference to the accompanying drawings. In the various drawings, same or corresponding parts will be assigned same or corresponding reference numerals, and redundant description will be omitted. In the present specification, the X-axis direction, the Y-axis direction and the Z-axis direction are orthogonal to each other, and the X-axis and Y-axis directions are horizontal directions whereas the Z-axis direction is a vertical direction.

First, with reference to FIG. 1 and FIG. 2, a laser processing apparatus 1 according to the present exemplary embodiment will be described. The laser processing apparatus 1 is configured to perform a laser processing on a substrate W obtained by slicing a single crystal ingot.

The substrate W is a silicon wafer or a compound semiconductor wafer. Although the compound semiconductor wafer is not particularly limited, it may be, for example, a GaAs wafer, a SiC wafer, a GaN wafer or an InP wafer. The substrate W is a bare wafer.

The substrate W includes, as shown in FIG. 3A, a first main surface Wa, and a second main surface Wb opposite to the first main surface Wa. The first main surface Wa and the second main surface Wb are formed by the slicing of the single crystal ingot. During the slicing, fragment may adhere to the first main surface Wa and the second main surface Wb. The fragment is, for example, an abrasive grain of a cutting blade.

As shown in FIG. 3B, the laser processing apparatus 1 is configured to remove a surface layer Wa1 from the entire first main surface Wa of the substrate W1, and removes a surface layer Wb1 from the entire second main surface Wb of the substrate W1. Accordingly, the fragment adhering to the substrate W during the slicing of the single crystal ingot is removed, and generation of a defect in the substrate W due to the fragment is suppressed.

As shown in FIG. 1, the laser processing apparatus 1 includes a carry-in/out station 2, a processing station 3, and a control module 9. The carry-in/out station 2 and the processing station 3 are arranged in this order in the positive X-axis direction.

The carry-in/out station 2 includes a placing table 20 and a transfer section 23. The placing table 20 includes a plurality of placement plates 21. A plurality of placement plates 21 are arranged in a row in the Y-axis direction. Cassettes C are respectively disposed on the plurality of (for example, three) placements plates 21. One of the cassettes C accommodates therein a plurality of substrates W before being processed. Another cassette C accommodates therein a plurality of substrates W after being processed. The other cassette C accommodates therein a plurality of substrates W having abnormality that has occurred during the processing. Further, the number of the placement plates 21 and the number of the cassettes C are not particularly limited.

The transfer section 23 is disposed adjacent to the positive X-axis side of the placing table 20 and the negative X-axis side of the processing station 3. The transfer section 23 is equipped with a transfer arm 24 configured to hold the substrate W. The transfer arm 24 is configured to be movable in horizontal directions (both in the X-axis direction and the Y-axis direction) and a vertical direction and pivotable around a vertical axis. The transfer arm 24 transfers the substrates W between the cassettes C on the placing table 20 and a third processing block G3 of the processing station 3.

The processing station 3 is equipped with a first processing block G1, a second processing block G2, the third processing block G3, a fourth processing block G4, and a transfer block G5. The transfer block G5 is disposed in an area surrounded by the first processing block G1, the second processing block G2, the third processing block G3, and the fourth processing block G4. The third processing block G3 is disposed adjacent to the negative X-axis side of the transfer block G5.

The transfer block G5 is equipped with a transfer arm 38 configured to hold the substrate W. The transfer arm 38 is configured to be movable in horizontal directions (both in the X-axis direction and the Y-axis direction) and a vertical direction and pivotable around a vertical axis. The transfer arm 38 transfers the substrates W between the first processing block G1, the second processing block G2, the third processing block G3, and the fourth processing block G4.

The first processing block G1 is disposed adjacent to the positive Y-axis side of the transfer block G5. The first processing block G1 has, for example, a laser processing module 31. The laser processing module 31 is configured to radiate a laser beam to the first main surface Wa of the substrate W, and removes the surface layer Wa1 from the entire first main surface Wa. Further, the laser processing module 31 is configured to radiate a laser beam to the second main surface Wb of the substrate W, and removes the surface layer Wb1 from the entire second main surface Wb. The surface layers Wa1 and Wb1 absorb the laser beams to be scattered while undergoing a change of state from a solid phase to a gaseous phase or while remaining in the solid phase.

The second processing block G2 is disposed adjacent to the negative Y-axis side of the transfer block G5. The second processing block G2 has, by way of example, a cleaning module 32 and an etching module 33. The cleaning module 32 is configured to scrub-clean the substrate W to remove, from the substrate W, debris scattered from a radiation point of the laser beam. The etching module 33 is configured to etch the substrate W to reduce surface roughness of the substrate W or to remove a discoloration layer caused by the radiation of the laser beam. Here, when the removal of the debris is not required, the cleaning module 32 is unnecessary. Also, when the reduction of the surface roughness or the removal of the discoloration layer is not required, the etching module 33 is not necessary. The layout of the cleaning module 32 and the etching module 33 is not limited to the example of FIG. 2.

The third processing block G3 is disposed adjacent to the negative X-axis side of the transfer block G5. As illustrated in FIG. 2, the third processing block G3 has, for example, a transition module 34, a waveform measuring module 35, and an inverting module 36. The transition module 34 is configured to deliver the substrate W between the transfer arm 24 of the carry-in/out station 2 and the transfer arm 38 of the processing station 3. The waveform measuring module 35 is configured to measure a waveform of the first main surface Wa of the substrate W. Also, the waveform measuring module 35 is configured to measure a waveform of the second main surface Wb of the substrate W. For the measurement of the waveforms, a commercially available three-dimensional shape measuring instrument or the like is used. The inverting module 36 inverts the substrate W. The layout of the transition module 34, the waveform measuring module 35 and the inverting module 36 is not limited to the example of FIG. 2.

The fourth processing block G4 is disposed adjacent to the positive X-axis side of the transfer block G5. The fourth processing block G4 has, by way of example, a grinding module 37. The grinding module 37 is configured to grind the first main surface Wa of the substrate W to improve flatness of the first main surface Wa. Further, the grinding module 37 is also configured to grind the second main surface Wb of the substrate W to improve flatness of the second main surface Wb. Here, when sufficient flatness is achieved by the radiation of the laser beams, the grinding module 37 is unnecessary.

Moreover, the processing station 3 needs to have the laser processing module 31 at least. The type, the layout and the number of the modules constituting the processing station 3 are not limited to those shown in FIG. 1 and FIG. 2.

The control module 9 is, for example, a computer, and includes a CPU (Central Processing Unit) 91 and a recording medium 92 such as a memory. The recording medium 92 stores therein a program for controlling various processings performed in the laser processing apparatus 1. The control module 9 controls an operation of the laser processing apparatus 1 by causing the CPU 91 to execute the program stored in the recording medium 92.

Now, with reference to FIG. 4, a laser processing method according to the present exemplary embodiment will be described. Processes S101 to S109 shown in FIG. 4 are performed under the control of the control module 9.

First, the transfer arm 24 of the carry-in/out station 2 takes out the substrate W from the cassette C on the placing table 20, and transfers it to the transition module 34. Subsequently, the transfer arm 38 of the processing station 3 receives the substrate W from the transition module 34, and transfers it to the waveform measuring module 35. In the meantime, the substrate W is held horizontally with the first main surface Wa thereof facing upwards.

Then, the waveform measuring module 35 measures the waveform of the first main surface Wa of the substrate W (process S101). The measurement of the waveform is performed in a natural state where no external force other than gravity and its drag force, for example, an attraction force, is acting. The natural state is a state in which the substrate W is not deformed and a stress on a substrate surface is substantially zero. For example, as shown in FIG. 5, the waveform is measured in the state where the substrate W is simply placed on a horizontal surface of a stage 35a. The waveform measuring module 35 has a displacement gauge 35b. The displacement gauge 35b is configured to measure a height distribution of a top surface (for example, the first main surface Wa) of the substrate W. Although the displacement meter 35b is of a non-contact type in the present exemplary embodiment, it may be of a contact type. The waveform measuring module 35 transmits the measurement data to the control module 9. After the above-described process S101, the transfer arm 38 takes out the substrate W from the waveform measuring module 35, and transfers it to the laser processing module 31.

Subsequently, the laser processing module 31 performs the laser processing on the first main surface Wa of the substrate W (process S102). As a specific liquid, as illustrated in FIG. 6, the laser processing module 31 radiates a laser beam LB to the first main surface Wa while moving a position of a radiation point P across the entire first main surface Wa. As a result, the surface layer Wa1 is removed from the entire first main surface Wa.

Fragment is attached to the surface layer Wa1 during the slicing of the single crystal ingot. For example, if grinding (including polishing) is performed on the substrate W while the fragment is still attached, this fragment is pressed against the substrate W, resulting in a defect in the substrate W. The generated defect can be enlarged when etching is performed afterwards.

According to the present exemplary embodiment, since the surface layer Wa1 is removed, the fragment adhering to the surface layer Wa1 can be removed. In addition, since the surface layer Wa1 is removed, the fragment that cannot be removed by the brush cleaning or the like can also be removed. Accordingly, generation of a defect in the substrate W due to the fragment can be suppressed.

Further, the laser processing module 31 may reduce the waveform of the first main surface Wa at the time of removing the surface layer Wa1. A removing amount is controlled by adjusting a total radiation amount (unit: J), which is the product of an output (unit: W) of the laser beam LB and a radiation time. The larger the total radiation amount is, the larger the removing amount may be.

Referring to the measurement data of the waveform measuring module 35, the control module 9 controls the total radiation amount of the laser beam LB per unit area of the first main surface Wa so as to reduce the waveform of the first main surface Wa. This control includes at least one selected from a control of the output of a light source 31b and a control of the radiation time.

If, for example, the substrate W is pressed against a surface plate and polished in order to reduce the waveform of the first main surface Wa, the substrate W is elastically deformed. As a result, it becomes difficult to reduce the waveform of the substrate W. Furthermore, the fragment is pressed against the substrate W, resulting in the defect in the substrate W.

According to the present exemplary embodiment, since the control module 9 controls the total radiation amount per unit area by referring to the measurement data of the waveform of the first main surface Wa in the natural state, the waveform can be efficiently reduced, so that the first main surface Wa can be efficiently flattened.

The laser processing of the first main surface Wa is performed in the natural state. For example, it is performed in the state where the substrate W is simply placed on the horizontal surface of the stage 31a. Even if a foreign material exists between the substrate W and the stage 31a, the substrate W does not have the defect because the foreign material is not pressed against the substrate W.

In addition, unlike the measurement of the waveform, the laser processing of the first main surface Wa may be performed in the state where the substrate W is attracted to the horizontal surface of the stage 31a. Since the removing amount of the surface layer Wa1 depends on the total radiation amount, it is still possible to reduce the waveform. In addition, the displacement of the substrate W can be suppressed by the attraction.

Upon the completion of the above-described process S102, the transfer arm 38 takes out the substrate W from the laser processing module 31, and transfers it to the cleaning module 32.

Afterwards, the cleaning module 32 scrub-cleans the substrate W (process S103) to remove, from the substrate W, the debris scattered from the radiation point P of the laser beam LB. After the process S103, the transfer arm 38 takes out the substrate W from the cleaning module 32, and transfers it to the inverting module 36.

Next, the inverting module 36 inverts the substrate W (process S104) to allow the second main surface Wb of the substrate W to face up. After the above-described process S104, the transfer arm 38 takes out the substrate W from the inverting module 36, and transfers it to the waveform measuring module 35 again. In the meanwhile, the substrate W is held horizontally with the second main surface Wb facing upwards.

Thereafter, the waveform measuring module 35 measures the waveform of the second main surface Wb of the substrate W (process S105). The measurement of the waveform is performed in the natural state. For example, it is performed in the state where the substrate W is simply placed on the horizontal surface of the stage 35a. The displacement gauge 35b measures the height distribution of the second main surface Wb of the substrate W. The waveform measuring module 35 transmits the measurement data to the control module 9. After the above-described process S105, the transfer arm 38 takes out the substrate W from the waveform measuring module 35, and transfers it to the laser processing module 31 again.

Then, the laser processing module 31 performs the laser processing on the second main surface Wb of the substrate W (process S106). Specifically, the laser processing module 31 radiates the laser beam LB to the second main surface Wb while moving the position of the radiation point P across the entire second main surface Wb. As a result, the surface layer Wb1 is removed from the entire second main surface Wb.

According to the present exemplary embodiment, since the surface layer Wb1 is removed, the fragment adhering to the surface layer Wb1 can be removed. In addition, since the surface layer Wb1 is removed, the fragment that cannot be removed by the brush cleaning or the like can also be removed. Accordingly, the generation of the defect in the substrate W due to the fragment can be suppressed.

Further, the laser processing module 31 may reduce the waveform of the second main surface Wb when removing the surface layer Wb1. A removing amount is controlled by adjusting a total radiation amount (unit: J), which is the product of an output (unit: W) of the laser beam LB and a radiation time. The larger the total radiation amount is, the larger the removing amount may be.

Referring to the measurement data of the waveform measuring module 35, the control module 9 controls the total radiation amount of the laser beam LB per unit area of the second main surface Wb so as to reduce the waveform of the second main surface Wb. This control includes at least one selected from a control of the output of the light source 31b and a control of the radiation time.

According to the present exemplary embodiment, since the control module 9 controls the total radiation amount per unit area by referring to the measurement data of the waveform of the second main surface Wb in the natural state, the waveform can be efficiently reduced, so that the second main surface Wb can be efficiently flattened.

The laser processing of the second main surface Wb is performed in the natural state, for example, in the state where the substrate W is simply placed on the horizontal surface of the stage 31a. Even if a foreign material exists between the substrate W and the stage 31a, the substrate W does not have the defect because the foreign material is not pressed against the substrate W.

Further, unlike the measurement of the waveform, the laser processing of the second main surface Wb may be performed in the state where it is attracted to the horizontal surface of the stage 31a. Since the removing amount of the surface layer Wb1 depends on the total radiation amount, it is still possible to reduce the waveform. In addition, the displacement of the substrate W can be suppressed by the attraction.

Upon the completion of the process S106, the transfer arm 38 takes out the substrate W from the laser processing module 31, and transfers it to the cleaning module 32 again.

Next, the cleaning module 32 scrub-cleans the substrate W (process S107) to remove, from the substrate W, the debris scattered from the radiation point P of the laser beam LB. After the above-described process S107, the transfer arm 38 takes out the substrate W from the cleaning module 32, and transfers it to the etching module 33.

Thereafter, the etching module 33 etches the substrate W (process S108) to reduce the surface roughness of the substrate W or to remove the discoloration layer caused by the radiation of the laser beam. The etching module 33 performs, for example, wet etching on the substrate W, and simultaneously etches the first main surface Wa and the second main surface Wb of the substrate W. Further, the etching module 33 may dry-etch the substrate W, and may etch the first main surface Wa and the second main surface Wb of the substrate W in sequence. After the above-described process S108, the transfer arm 38 takes out the substrate W from the etching module 33, and transfers it to the grinding module 37.

Subsequently, the grinding module 37 grinds the substrate W (process S109) to improve the flatness of the substrate W. The grinding module 37 grinds the first main surface Wa of the substrate W to improve the flatness of the first main surface Wa. Also, the grinding module 37 may grind the second main surface Wb of the substrate W to improve the flatness of the second main surface Wb. The grinding of the first main surface Wa and the grinding of the second main surface Wb are performed in sequence, and the substrate W is inverted in the middle. The grinding also includes polishing. The order of the grinding (process S109) of the substrate W and the etching (process S108) of the substrate W may be reversed. By way of example, the substrate W may be first ground, both surfaces of the substrate W may be then cleaned, and, thereafter, the substrate W may be etched. The etching may be either double-sided etching or single-sided etching.

Finally, the transfer arm 38 takes out the substrate W from the grinding module 37, and transfers it to the transition module 34. Next, the transfer arm 24 of the carry-in/out station 2 takes out the substrate W from the transition module 34, and accommodates the substrate W in the cassette C on the placing table 20.

Now, referring to FIG. 6, the laser processing module 31 according to the present exemplary embodiment will be described. The laser processing module 31 is equipped with, for example, a stage 31a as a holder, a light source 31b, and a galvano scanner 31c as a moving unit. Further, the laser processing module 31 is also equipped with an fθ lens 31d, a homogenizer 31e, and an aperture 31f.

The stage 31a is configured to hold the substrate W. For example, the stage 31a holds the substrate W horizontally from below with the main surface of the substrate W, to which the laser beam LB is radiated, facing upwards. The stage 31a holds the substrate W in the natural state without attracting it. In addition, although the stage 31a of the present exemplary embodiment does not attract the substrate W, it may be configured to attract it. In the latter case, the stage 31a is a vacuum chuck or an electrostatic chuck.

The light source 31b is configured to oscillate the laser beam LB to be radiated to the top surface (e.g., the first main surface Wa) of the substrate W. The laser beam LB is absorbable by the substrate W. When the substrate W is a silicon wafer, the laser beam LB is, for example, UV light. The substrate W absorbs the laser beam LB, and is scattered while undergoing a change of a state thereof from a solid phase to a gas phase or scattered while remaining in the solid phase. As a result, the surface layer Wa1 of the first main surface Wa of the substrate W is removed. The laser beam LB may be radiated to converge on the top surface of the substrate W. In the present exemplary embodiment, the radiation point P is a light-converging point where the power density is highest. However, the radiation point P may not be the light-converging point.

The light source 31b is, for example, a pulse laser. A radiation time per pulse is, for example, 30 nsec or less. If the radiation time per pulse is 30 nsec or less, the laser beam LB having high power density can be radiated to the substrate W in a short time, so that overheating of the substrate W can be suppressed. Therefore, deterioration of the substrate W due to heat can be suppressed, and generation of a discoloration layer, for example, can be suppressed. The radiation time per pulse is desirably 10 psec or less. If the radiation time per pulse is 10 psec or less, the deterioration of the substrate W due to the heat can be suppressed even if the radiation point P is formed multiple times at the same place.

The galvano scanner 31c is disposed above the substrate W held by the stage 31a, for example. With the galvano scanner 31c, the position of the radiation point P of the laser beam LB on the top surface of the substrate W can be moved without moving the stage 31a. Even when the stage 31a does not attract the substrate W, if the stage 31a is not moved, positional deviation of the substrate W with respect to the stage 31a does not occur. Therefore, the position of the radiation point P can be controlled with high precision.

The galvano scanner 31c includes two sets of a galvano mirror 31c1 and a galvano motor 31c2 (only one set is shown in FIG. 6). One of the two galvano motors 31c2 rotates one of the galvano mirrors 31c1 to displace the radiation point P in the X-axis direction. The other galvano motor 31c2 rotates the other galvano mirror 31c1 to displace the radiation point P in the Y-axis direction.

Further, although the moving unit of the present exemplary embodiment is the galvano scanner 31c, the technique of the present disclosure is not limited thereto. The moving unit may include a polygon scanner instead of the galvano scanner 31c. As compared with the galvano scanner 31c, the polygon scanner has a faster scanning speed and can use a high-frequency pulse laser. The moving unit needs to move the position of the radiation point P of the laser beam LB on the first main surface Wa of the substrate W in the state that the substrate W is held by the stage 31a. For example, the moving unit may be configured to move the stage 31a in the X-axis direction and the Y-axis direction, and may have a motor and a ball screw mechanism or the like that converts a rotational motion of the motor into a linear motion of the stage 31a. Moreover, the moving unit may have a mechanism configured to rotate the stage 31a around a vertical axis.

The fθ lens 31d is configured to form a focal plane perpendicular to the Z-axis direction. While the galvano scanner 31c is moving the position of the radiation point P in the X-axis direction or the Y-axis direction, the fθ lens 31d maintains the position of the radiation point P in the Z-axis direction on the focal plane, and also maintains the shape and the size of the radiation point P on the focal plane. As a result, as will be described later, rectangular radiation points P can be two-dimensionally arranged regularly on the top surface of the substrate W without any gaps therebetween. The height of the radiation point P is the height of the focal plane.

The homogenizer 31e is configured to convert an intensity distribution of the laser beam LB from a Gaussian distribution shown in FIG. 7A to a top hat distribution shown in FIG. 7B, and is configured to homogenize the intensity distribution.

The aperture 31f is configured to form the cross-sectional shape of the laser beam LB into a rectangle. This rectangle includes a square as well as a rectangle. The aperture 31f is a light shielding film having a rectangular opening. The opening allows the laser beam LB in a range indicated by an arrow D in FIG. 7B, for example, to pass therethrough.

With the homogenizer 31e and the aperture 31f, the rectangular radiation points P having the uniform intensity distribution can be formed. By two-dimensionally arranging the radiation points P regularly without any gaps therebetween, the total radiation amount of the laser beam LB per unit area can be controlled with high precision.

As shown in FIG. 8A, the radiation point P is a rectangle having a uniform intensity distribution, and two sides of this rectangle are parallel to the X-axis direction with the other two sides thereof parallel to the Y-axis direction. A dimension X0 of the radiation point P in the X-axis direction may be equal to or different from a dimension Y0 of the radiation point P in the Y-axis direction. In FIG. 8B and FIG. 8C, they are same.

As shown in FIG. 8A, while oscillating the laser beam LB in a pulse shape, the control module 9 moves the radiation point P by X0 in the X-axis direction during an off-time of the pulse, thus arranging the radiation points P in a row over the entire X-axis side of the top surface of the substrate W without any gaps therebetween. Thereafter, while oscillating the laser beam LB in the pulse shape, the control module 9 repeats a movement of the radiation point P by Y0 in the Y-axis direction during the off-time of the pulse and the movement of the radiation point P by X0 in the X-axis direction during the off-time of the pulse, thus arranging the radiation points P two-dimensionally over the entire top surface of the substrate W without any gaps therebetween.

Alternatively, as shown in FIG. 8B, while oscillating the laser beam LB in the pulse shape, the control module 9 moves the radiation point P by a half of X0 in the X-axis direction during the off-time of the pulse, thus arranging the radiation points P in a row while overlapping them over the entire X-axis side of the top surface of the substrate W. Thereafter, while oscillating the laser beam LB in the pulse shape, the control module 9 repeats a movement of the radiation point P by Y0 in the Y-axis direction during the off-time of the pulse and the movement of the radiation point P by the half of X0 in the X-axis direction during the off-time of the pulse, thus arranging the radiation points P two-dimensionally over the entire top surface of the substrate W without any gaps therebetween. In addition, while oscillating the laser beam LB in the pulse shape, the control module 9 may move the radiation point P by a half of Y0 in the Y-axis direction during the off-time of the pulse instead of moving the radiation point P by Y0 in the Y-axis direction during the off-time of the pulse.

Alternatively, as illustrated in FIG. 8C, while oscillating the laser beam LB in the pulse shape, the control module 9 moves the radiation point P by twice as much as X0 in the X-axis direction during the off-time of the pulse, thus arranging radiation points P in a row while forming gaps SP over the entire X-axis side of the top surface of the substrate W. Subsequently, while oscillating the laser beam LB in the pulse shape again, the control module 9 moves the radiation point P by twice as much as X0 in the X-axis direction during the off-time of the pulse so as to fill the gaps SP with the radiation points P. Thereafter, while oscillating the laser beam LB in the pulse shape, the control module 9 repeats a movement of the radiation point P by Y0 in the Y-axis direction during the off-time of the pulse, the movement of the radiation point P by twice as much as X0 in the X-axis direction during the off-time of the pulse, and the movement of the radiation point by twice as much as X0 in the X-axis direction during the off-time of the pulse so as to fill the gaps SP with the radiation points P, thus arranging the radiation points P two-dimensionally without any gaps therebetween.

In addition, although the waveform measuring module 35 and the inverting module 36 are provided separately from the laser processing module 31 in the present exemplary embodiment, the technique of the present disclosure is not limited thereto. The laser processing module 31 may have the function of the waveform measuring module 35. Further, the laser processing module 31 may have the function of the inverting module 36.

So far, the exemplary embodiment of the laser processing apparatus and the laser processing method has been described. However, it should be noted that the present disclosure is not limited to the above-described exemplary embodiment. Various changes, modifications, replacements, addition, deletion and combinations may be made within the scope of the claims, and all of these are included in the scope of the inventive concept of the present disclosure.

The present application claims priority to Japanese Patent Application No. 2020-151606, field on Sep. 9, 2020, which application is hereby incorporated by reference in their entirety.

### EXPLANATION OF CODES

1: Laser processing apparatus
9: Control module (Controller)
31: Laser processing module
31a: Stage (Holder)
31b: Light source
31c: Moving unit (Galvano scanner)

1-16. (canceled)

17. A laser processing apparatus, comprising:
a holder configured to hold a substrate obtained by slicing a single crystal ingot;
a light source configured to oscillate a laser beam to be radiated to a first main surface of the substrate;
a moving unit configured to move a position of a radiation point of the laser beam on the first main surface of the substrate in a state that the substrate is held by the holder; and
a controller configured to control the light source and the moving unit,
wherein the controller controls the light source and the moving unit to radiate the laser beam to the first main surface of the substrate to remove a surface layer of the first main surface of the substrate, so that fragment adhering to the first main surface during the slicing of the single crystal ingot is removed.

18. The laser processing apparatus of claim 17, further comprising:
an inverting unit configured to invert the substrate,
wherein the controller controls the light source, the moving unit and the inverting unit to radiate the laser beam to a second main surface of the substrate inverted by the inverting unit to remove a surface layer of the second main surface, so that fragment adhering to the second main surface during the slicing of the single crystal ingot is removed.

19. The laser processing apparatus of claim 17, further comprising:
a grinding module configured to grind the first main surface,
wherein the controller performs a control of grinding the first main surface by the grinding module after the fragment adhering to the first main surface is removed.

20. The laser processing apparatus of claim 17, further comprising:
an etching module configured to etch the first main surface,
wherein the controller performs a control of etching the first main surface by the etching module after the fragment adhering to the first main surface is removed.

21. The laser processing apparatus of claim 17,
wherein the holder holds the substrate without deforming the substrate.

22. The laser processing apparatus of claim 17, further comprising:
a waveform measuring unit configured to measure a waveform of the first main surface in a state that a surface stress of the substrate is substantially zero,
wherein the controller performs a control of reducing the waveform of the first main surface by controlling, while referring to measurement data of the waveform of the first main surface, a total radiation amount of the laser beam per unit area of the first main surface.

23. A laser processing method, comprising:
placing a substrate obtained by slicing a single crystal ingot; and
removing, by radiating a laser beam to a first main surface of the substrate to remove a surface layer of the first main surface, fragment adhering to the first main surface during the slicing of the single crystal ingot.

24. The laser processing method of claim 23, further comprising:
inverting the substrate; and
removing, by radiating the laser beam to a second main surface of the substrate opposite to the first main surface to remove a surface layer of the second main surface, fragment adhering to the second main surface during the slicing of the single crystal ingot.

25. The laser processing method of claim 23, further comprising:
grinding the first main surface after the removing of the fragment adhering to the first main surface.

26. The laser processing method of claim 23, further comprising:
etching the first main surface after the removing of the fragment adhering to the first main surface.

27. The laser processing method of claim 23,
wherein the placing of the substrate obtained by slicing the single crystal ingot includes holding the substrate without deforming the substrate.

28. The laser processing method of claim 23, further comprising:
measuring a waveform of the first main surface in a state that a surface stress of the substrate is substantially zero; and
performing a control of reducing the waveform of the first main surface by controlling, while referring to measurement data of the waveform of the first main surface, a total radiation amount of the laser beam per unit area of the first main surface.
